(19) United States
(12) Patent Application Publication
(10) Pub. No.: US 2013/0214658 A1
(43) Pub. Date: Aug. 22, 2013

(54) SERVER CABINET

(71) Applicant: AN-GANG LIANG, Shenzhen City (CN)

(72) Inventor: AN-GANG LIANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/473,628

(22) Filed: May 17, 2012

(30) Foreign Application Priority Data
Feb. 16, 2012 (CN) 201210034950.7

(51) Int. Cl. H05K 5/02; H05K 7/14

(52) U.S. Cl. 312/223.2; 312/223.6

(57) ABSTRACT

A server cabinet includes a housing and a cable management bracket. The cable management bracket is connected between a front end and a rear end of a side of the housing. The cable management bracket longitudinally defines a number of receiving spaces for cables extending through.

### BACKGROUND

1. Technical Field

The present disclosure relates to a server cabinet.

2. Description of Related Art

Fans are generally mounted behind servers in the server cabinet. A plurality of cables is provided for connecting the fans and servers. However, due to the large number of cables, it is often troublesome to keep the cables in an organized manner.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a server cabinet.

FIG. 2 is similar to FIG. 1, but viewed from a different perspective.

FIG. 3 is a partially exploded, isometric view of the cabinet of FIG. 2, wherein the cabinet includes a receiving member.

FIG. 4 is an enlarged view of a circled portion IV of FIG. 3.

FIG. 5 is an enlarged view of the receiving member of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

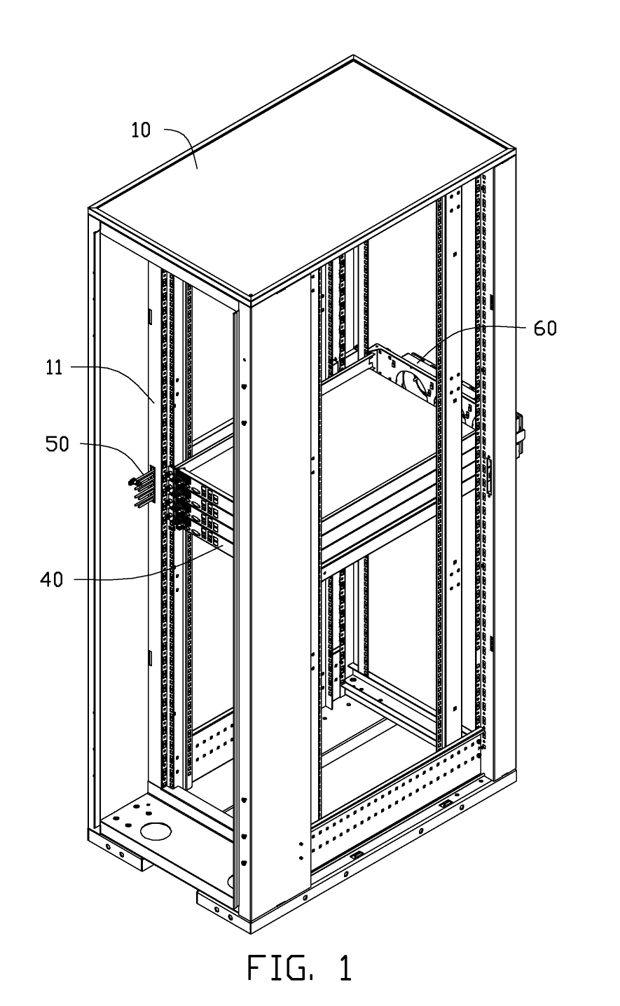

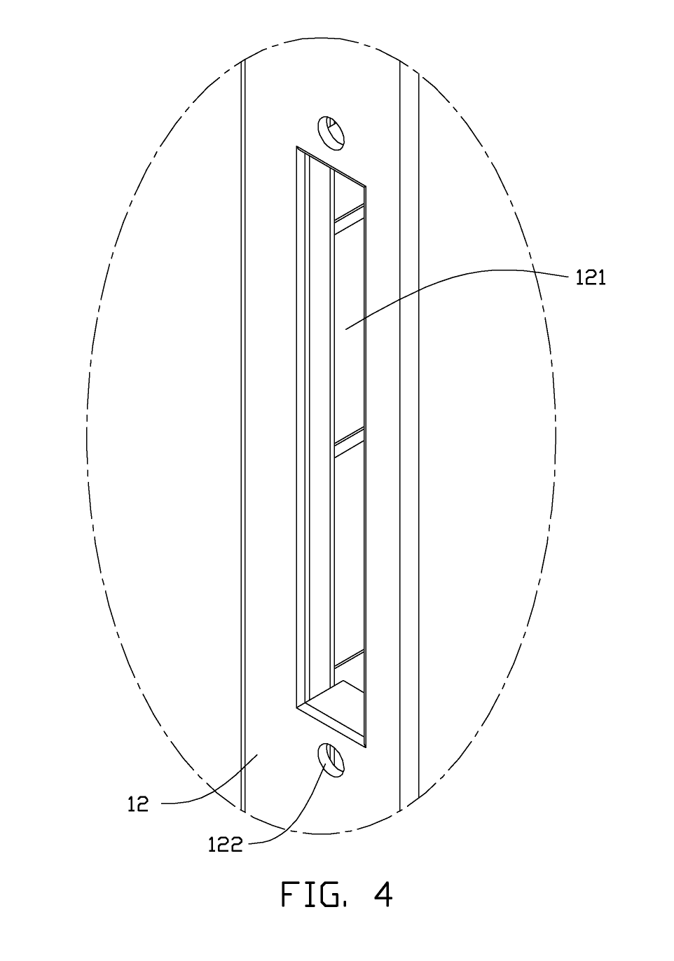

FIGS. 1-4 show an exemplary embodiment of a server cabinet including a housing 10 and a cable management bracket 100. The cable management bracket 100 includes a receiving member 20 and a cover 30.

Two first posts 11 are respectively formed on opposite sides of a front end of the housing 10. Two second posts 12 are respectively formed on opposite sides of a rear end of the housing 10. A plurality of servers 40 is perpendicularly mounted among the first posts 11 and second posts 12. A fan module 60 is mounted behind the servers 40, for cooling the servers 40. An opening 112 is defined in each first post 11, extending through a front side and a rear side of the first post 11 and adjoining the server 40. Two stop tabs 113 extend backward from each first post 11, respectively adjoining a top end and a bottom end of the opening 112. A through slot 121 is defined in each second post 12, extending through a front side and a rear side of the second post 12. Two locking holes 122 are defined in the rear side of each second post 12, respectively adjacent to a top end and a bottom end of the corresponding through slot 121. The openings 112 align with the corresponding through slots 121.

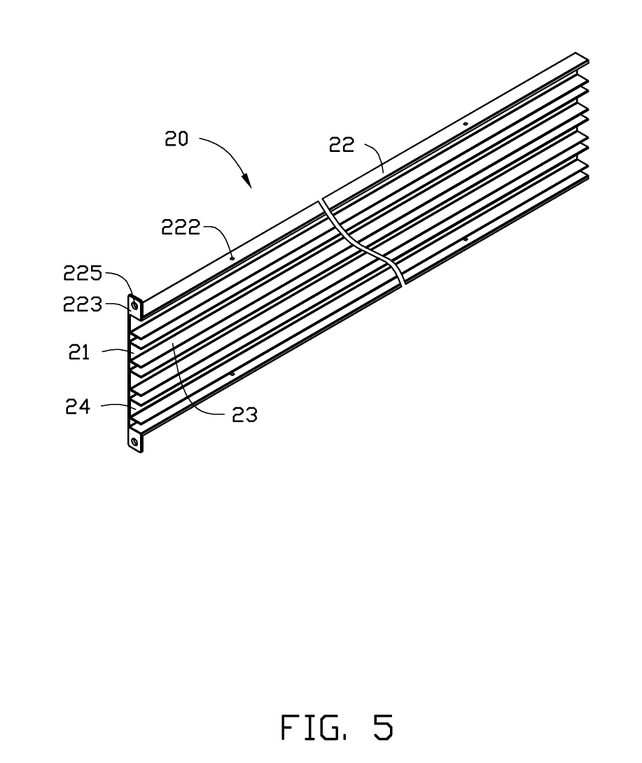

FIG. 5 shows the receiving member 20 including a long base plate 21, and two side plates 22 perpendicularly extending from opposite sides of the base plate 21. A plurality of partition plates 23 perpendicularly extends from a side surface of the base plate 21 between and parallel to the side plates 22. Every two adjacent partition plates 23 and the base plate 21 bound a receiving space 24, and each side plate 22 and an adjacent partition plate 23 bound a receiving space 24, together with the base plate 21. Two mounting holes 222 are defined in each side plate 22. Two locking tabs 223 respectively perpendicularly extend out from first ends of the side plates 22, away from each other. A through hole 225 is defined in each locking tab 223.

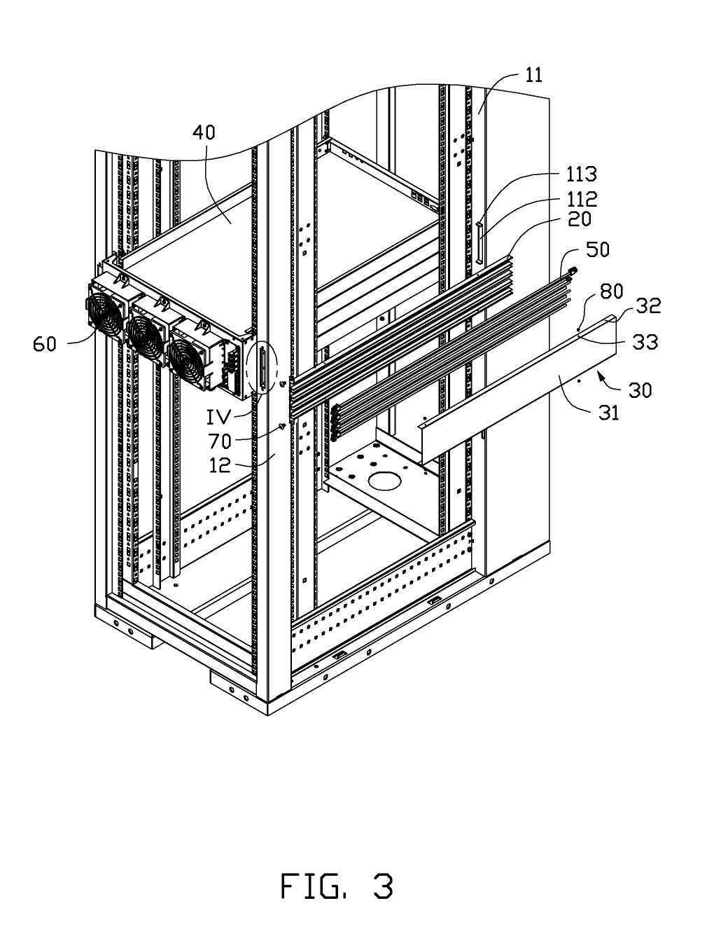

FIG. 3 shows the cover 30 including a covering plate 31 and two extension plates 32 perpendicularly extending from opposite sides of the covering plate 31. Two through holes 33 are defined in each extension plate 32.

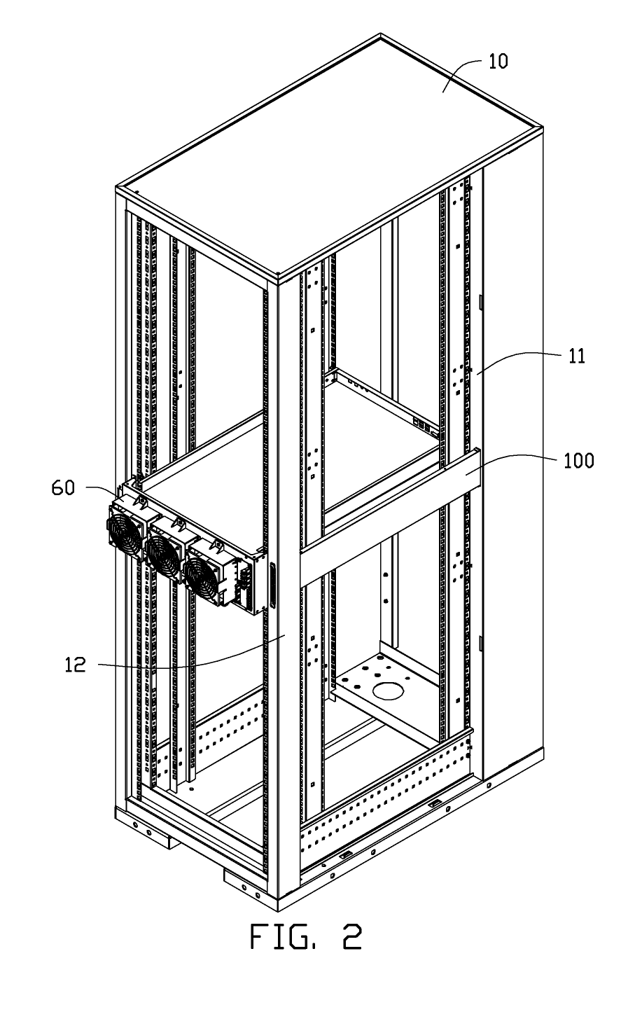

FIGS. 2 and 3 show in assembly, a second end of the receiving member 20 away from the locking tabs 223 extends through one of the through slots 121 from the rear side of the corresponding second post 12, to be sandwiched between the stop tabs 113 of the corresponding first post 11. The partition plates 23 face away from the servers 40. The locking tabs 223 abut against the rear side of the corresponding second post 12. Two screws 70 extend through the through holes 225, and engage in the corresponding locking holes 122. Therefore, the receiving member 20 is fastened to the housing 10. First ends of a plurality of cables 50 are connected to the fan module 60, second ends of the cables 50 extend through the corresponding receiving spaces 24 to be connected to front ends of the corresponding servers 40. The cover 30 is covered on the receiving member 20, with the covering plate 31 facing the base plate 21. The extension plates 32 abut against outer surfaces of the corresponding side plates 22. Four screws 80 extend through the corresponding through holes 33 and engage in the corresponding mounting holes 222. Therefore, the cover 30 is mounted to the receiving member 20, to prevent the cables 50 from disengaging from the receiving member 20.

If more servers 40 are mounted to the housing 10, more corresponding openings 112 and through slots 121 can be defined, and more corresponding receiving members 20 and covers 30 can be provided.

The cables 50 are received in the corresponding receiving spaces 24 of the receiving member 20, so the cables 50 are managed in an organized way.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A server cabinet, comprising:
a housing; and
a cable management bracket connected between a front end and a rear end of a first side of the housing, the cable management bracket defining a plurality of receiving spaces extending along a direction from the front end to the rear end for cables extending through.

2. The server cabinet of claim 1, wherein the housing comprises a first post formed at a front end of the first side of the housing, and a second post formed at a rear end of the first side of the housing, the cable management bracket is mounted between the first post and second post, substantially perpendicular to the first and the second posts.

3. The server cabinet of claim 2, wherein an opening is defined in the first post, two stop tabs extend backward from the first post, respectively adjoining a top end and a bottom end of the opening, the second post defines a through slot aligning with the opening, the cable management bracket comprises a receiving member, the receiving member comprises a base plate and two side plates perpendicularly extending from opposite sides of the base plate, two locking tabs perpendicularly extend from first ends of the side plates, away from each other, the first end of the receiving member is received in the through slot, the locking tabs are fastened to a rear side of the second bracket adjacent to the through slot, a second end of the receiving member is sandwiched between the stop tabs.

4. The server cabinet of claim 3, wherein a plurality of partition plates extends from a side surface of the base plate, between and parallel to the side plates, every two adjacent partition plates bound one of the receiving spaces, each side plate and an adjacent partition plate bound one of the receiving spaces.

5. The server cabinet of claim 3, wherein the cable management bracket further comprises a cover for covering the receiving member, the cover comprises a covering plate facing the base plate and two extension plates extending from opposite sides of the covering plate to be fastened to outer sides of the corresponding side plates.

6. The server cabinet of claim 1, wherein a plurality of servers is mounted in the housing, a fan module is mounted behind the servers and connected to the servers by the cables.
